(19) United States
(12) Patent Application Publication
(10) Pub. No.: US 2025/0351279 A1
(43) Pub. Date: Nov. 13, 2025

(54) DISPLAY DEVICE AND MANUFACTURING METHOD OF DISPLAY DEVICE

(71) Applicant: Samsung Display Co., LTD., Yongin-si (KR)

(72) Inventors: CHEULJIN PARK, Yongin-si (KR); KYUNGROK KO, Yongin-si (KR); MANSOO KIM, Yongin-si (KR); SUNGWON KIM, Yongin-si (KR); JUHEE KIM, Yongin-si (KR); EUNWON SEO, Yongin-si (KR); DUCKYONG AHN, Yongin-si (KR)

(21) Appl. No.: 19/072,398

(22) Filed: Mar. 6, 2025

(30) Foreign Application Priority Data
May 8, 2024 (KR) 10-2024-0060458

(51) Int. Cl. H05K 5/02; H10K 59/80

(52) U.S. Cl. CPC H05K 5/0217; H10K 59/80

(57) ABSTRACT

A manufacturing method of a display device includes preparing a mother substrate including a pattern part and a peripheral part disposed on an outside of the pattern part, forming an opening by etching the pattern part, forming a bridge by etching the peripheral part to be located adjacent to a border between the pattern part and the peripheral part, separating the pattern part and the peripheral part from each other by cutting the bridge, and coupling the pattern part on one surface of a display module, wherein a thickness of the bridge is smaller than a thickness of the pattern part.

This application claims priority to Korean Patent Application No. 10-2024-0060458, filed on May 8, 2024, and all the benefits accruing therefrom under 35 U.S.C. § 119, the content of which in its entirety is herein incorporated by reference.

### BACKGROUND

### 1. Field

The invention described herein relates to a display device, and more particularly to a display device and a manufacturing method of the display device.

### 2. Description of Related Art

An electronic device such as a smart phone, a digital camera, a laptop computer, a navigation device, and a smart television that provide images to a user includes a display device for displaying images. The display device creates images and provides the images through a display screen to a user.

Recently, with the development of the technology of a display device, various types of display devices are being developed. For example, various flexible display devices that are transformable into curved shapes, foldable, or rollable are being developed. A flexible display device is easy to carry and is capable of improving user convenience.

The display device may include a display module, a support part disposed under the display module, and a support sheet disposed between the display module and the support part.

### SUMMARY

Embodiments of the invention provide a display device and a manufacturing method of the display device including a support sheet that is easily manufactured and has an improved defect rate.

According to an embodiment, a manufacturing method of a display device includes preparing a mother substrate including a pattern part and a peripheral part disposed on an outside of the pattern part, forming an opening by etching the pattern part, forming a bridge by etching the peripheral part adjacent to a border between the pattern part and the peripheral part, separating the pattern part and the peripheral part from each other by cutting the bridge, and coupling the pattern part on one surface of a display module, wherein a thickness of the bridge is smaller than a thickness of the pattern part.

According to an embodiment, a display device includes a display module, a support part disposed under the display module, and a support sheet disposed between the display module and the support part. The support sheet includes a plurality of openings arranged in a first direction and a second direction intersecting the first direction, a first branch part disposed between the plurality of openings arranged in the second direction, a second branch part disposed between the plurality of openings arranged in the first direction, and a dummy part disposed in an opening to be located adjacent to an edge of the support sheet among the plurality of openings. The dummy part has a shape protruding from the second branch part in the second direction.

### BRIEF DESCRIPTION OF THE FIGURES

The above and other objects and features of the present disclosure will become apparent by describing in detail embodiments thereof with reference to the accompanying drawings.

FIG. 1A is a perspective view of a display device, according to an embodiment.

FIG. 1B is a perspective view of a display device, according to an embodiment.

FIG. 2A is a cross-sectional view corresponding to line I-I′ illustrated in FIG. 1A, according to an embodiment.

FIG. 2B is a cross-sectional view corresponding to line II-II' illustrated in FIG. 1B, according to an embodiment.

FIG. 3A is a perspective view illustrating a display module accommodated in the housing illustrated in FIG. 2A, according to an embodiment.

FIG. 3B is a perspective view illustrating a display module accommodated in the housing illustrated in FIG. 2A, according to an embodiment.

FIG. 4 is a view illustrating the cross section of the display module illustrated in FIGS. 3A, according to an embodiment.

FIG. 5 is a perspective view illustrating a portion of the support part illustrated in FIG. 2A, according to an embodiment.

FIG. 6A is a perspective view of the support sheet illustrated in FIG. 2A, according to an embodiment.

FIG. 6B is a plan view of a portion corresponding to a first area AA1 illustrated in FIG. 6A, according to an embodiment.

FIG. 6C is a plan view of a portion corresponding to a second area AA2 illustrated in FIG. 6B, according to an embodiment.

FIG. 7A is a perspective view for describing a manufacturing method of the support sheet illustrated in FIG. 6A, according to an embodiment.

FIG. 7B is a perspective view for describing a manufacturing method of the support sheet illustrated in FIG. 6A, according to an embodiment.

FIG. 7C is a perspective view for describing a manufacturing method of the support sheet illustrated in FIG. 6A, according to an embodiment.

FIG. 7D is a perspective view for describing a manufacturing method of the support sheet illustrated in FIG. 6A, according to an embodiment.

FIG. 7E is a perspective view for describing a manufacturing method of the support sheet illustrated in FIG. 6A, according to an embodiment.

FIG. 7F is a perspective view for describing a manufacturing method of the support sheet illustrated in FIG. 6A, according to an embodiment.

FIG. 8A is a perspective view of a portion corresponding to a third area AA3 illustrated in FIG. 7B, according to an embodiment.

FIG. 8B is a plan view of FIG. 8A, according to an embodiment.

FIG. 8C is a perspective view of a portion corresponding to a fourth area AA4 illustrated in FIG. 7B, according to an embodiment.

### DETAILED DESCRIPTION

In this specification, when a first component (or an area, a layer, a portion, etc.) is referred to as being “on,” “connected to,” or “coupled to” a second component, it means that they may be directly disposed/connected/coupled to the second component, or that a third component may disposed therebetween.

Like reference numerals refer to like elements. Additionally, in the drawings, the thickness, proportions, and dimensions of components are exaggerated for effective description of technical content. “And/or” includes all combinations of one or more that may be defined by associated components.

Terms such as first, second, etc. may be used to describe various components, but the components should not be limited by the terms. The terms are used only for the purpose of distinguishing one component from another. For example, a first component may be referred to as a second component without departing from the scope of the invention, and similarly, the second component may also be referred to as the first component. Singular expressions include plural expressions unless the context clearly dictates otherwise.

Additionally, terms such as “under,” “on the lower side,” “above,” and “on the upper side” are used to describe relationships between components shown in the drawings. The terms have relative concepts and are described based on directions indicated in the drawings.

It should be understood that a term such as “include” or “have” is intended to designate the presence of a feature, a number, a step, an operation, a component, a part, or a combination thereof described in the specification, but does not exclude in advance the possibility of the presence or addition of one or more other features, numbers, steps, operations, components, parts, or combinations thereof.

Unless otherwise defined, all terms (including technical terms and scientific terms) used in this specification have the same meaning as commonly understood by those skilled in the art to which the invention pertains. In addition, terms such as those defined in commonly used dictionaries should be interpreted as having meanings consistent with meanings they have in the context of a relevant technology, and unless explicitly defined herein, should not be interpreted as having overly idealistic or overly formal meanings.

Hereinafter, embodiments of the invention will be described with reference to drawings.

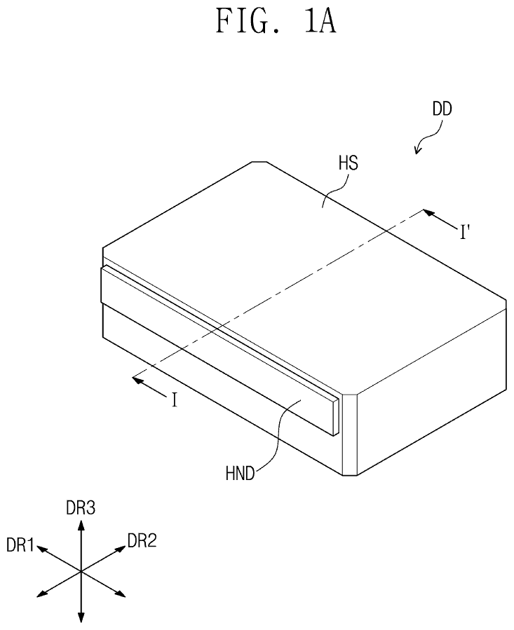

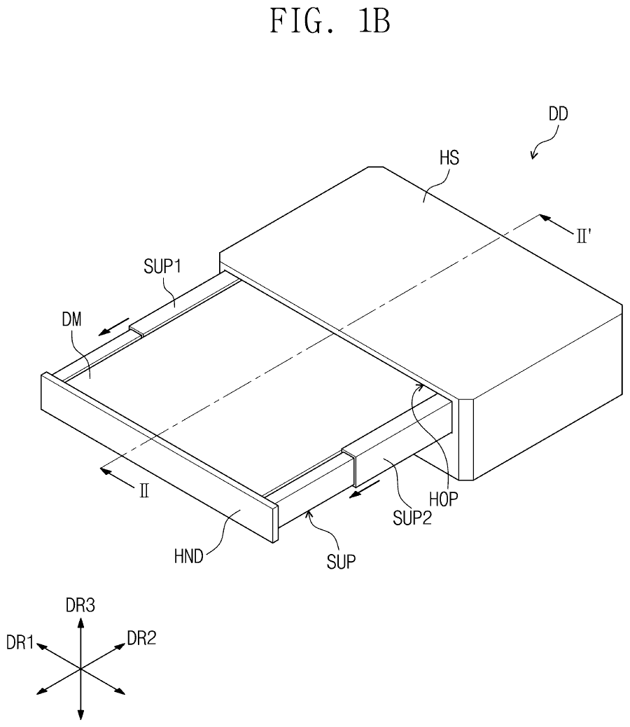

FIGS. 1A and 1B are perspective views of a display device, according to an embodiment.

In an embodiment, a display module DM of FIG. 1A is inserted into a housing HS, and the display module DM of FIG. 1B is pulled out of the housing HS.

In an embodiment and referring to FIGS. 1A and 1B, a display device DD may include a housing HS, a display module DM accommodated in the housing HS, a handle HND connected to the display module DM, and a support SUP disposed adjacent to each of the opposing sides of the display module DM.

In an embodiment, the housing HS may have a hexahedral shape, where the upper surface of the housing HS may have a rectangular shape having long sides extending in a first direction DR1 and short sides extending in a second direction DR2 that intersects the first direction DR1. However, the shape of the housing HS is not limited thereto.

Hereinafter, a direction that substantially perpendicularly intersects a plane defined by the first direction DR1 and the second direction DR2 is defined as a third direction DR3. In this specification, “when viewed on a plane” may mean a state viewed from the third direction DR3.

In an embodiment, a housing opening HOP may be defined on one side of the opposite sides of the housing HS that are opposite to each other in the second direction DR2. The housing opening HOP may be disposed adjacent more to the upper portion of the housing HS than to the lower portion of the housing HS.

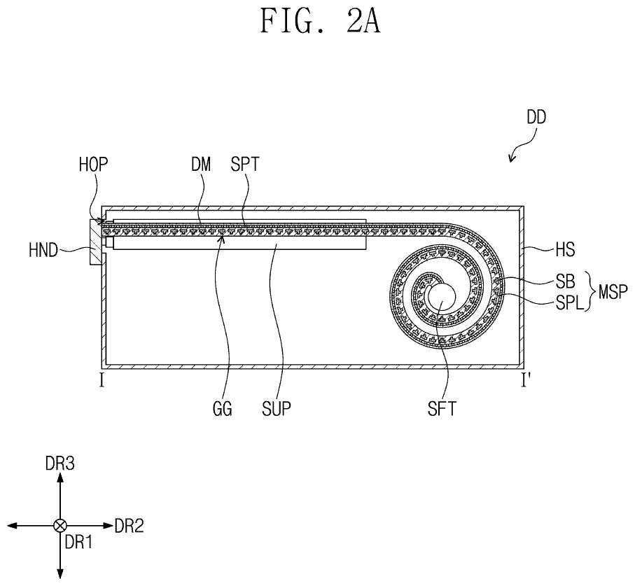

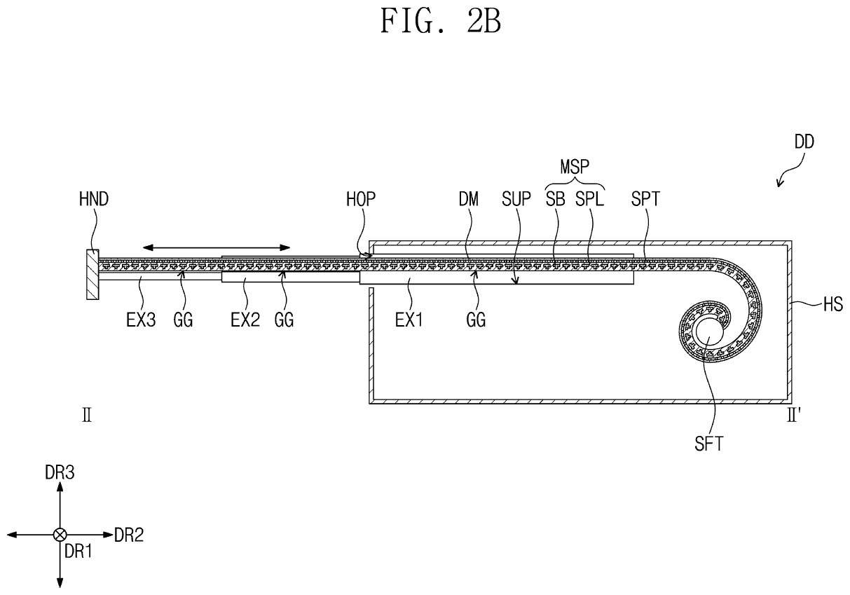

In an embodiment, the display module DM is wound on a shaft SFT (see FIG. 2A) disposed within the housing HS and may be inserted into and pulled out from the housing HS through the housing opening HOP. However, the display module DM is not limited thereto, and, in another embodiment, may be pulled out by sliding outward from the inside of the housing HS without using the shaft SFT (see FIG. 2A). A embodiment in which the display module DM is wound on the shaft SFT (see FIG. 2A) will be described in detail below.

In an embodiment, the handle HND may be disposed on the outside of the housing HS and located adjacent to the housing opening HOP. The handle HND may be disposed adjacent to the upper portion of the housing HS and may be moved in the second direction DR2. When the handle HND moves in the second direction DR2 to be away from the housing HS, the display module DM may be pulled out of the housing HS away from the housing opening HOP. The handle HND may be manipulated by a user.

In an embodiment and as illustrated in FIG. 1A, a state in which the display module DM is disposed inside the housing HS and is not exposed to the outside may be defined as a closed mode. As illustrated in FIG. 1B, an operation in which the display module DM is exposed to the outside of the housing HS may be defined as an open mode. In the open mode, the exposed portion of the display module DM may be extended.

In an embodiment, the support SUP may be disposed on opposing sides of the display module DM opposite to each other in the first direction DR1 to support the display module DM. The support SUP may include a first support SUP1 disposed adjacent to a first side of the display module DM and a second support SUP2 disposed adjacent to a second side of the display module DM. The first side of the display module DM and the second side of the display module DM may be the opposing sides of the display module DM that are disposed opposite to each other in the first direction DR1.

FIG. 2A is a cross-sectional view corresponding to line I-I′ illustrated in FIG. 1A, according to an embodiment. FIG. 2B is a cross-sectional view corresponding to line II-II′ illustrated in FIG. 1B, according to an embodiment.

In an embodiment and referring to FIG. 2A, the display device DD may further include the shaft SFT, a support part MSP, and a support sheet SPT. The shaft SFT, the support part MSP, and the support sheet SPT may be accommodated within the housing HS.

In an embodiment, within the housing HS, the shaft SFT may be disposed adjacent to a second side of the housing HS, which is disposed opposite to a first side of the housing HS in which the housing opening HOP is defined. When viewed in the first direction DR1, the shaft SFT may have a circular shape. For example, the shaft SFT may be a cylindrical shape extending in the first direction DR1 and the shaft SFT may rotate clockwise or counterclockwise about a rotational axis directed parallel to the first direction DR1. Although not shown, the display device DD may further include a drive part for rotating the shaft SFT.

In an embodiment, the display module DM may extend in the second direction DR2 to be wound on the shaft SFT. A first end of the display module DM may be connected to the shaft SFT. A portion of the display module DM may be wound on the shaft SFT, and another portion of the display module DM may be arranged to overlap the support SUP without being wound on the shaft SFT. A second end of the display module DM, which is opposite to the first end of the display module DM, may be connected to the handle HND. The second end of the display module DM may be disposed adjacent to the housing opening HOP.

In an embodiment, the front surface of the display module DM may be defined as a surface that displays an image. The support sheet SPT may be disposed on one surface of the display module DM and may be disposed on a surface opposite to the front surface of the display module DM. Hereinafter, the one surface of the display module DM may be defined as the surface disposed opposite to the front surface of the display module DM.

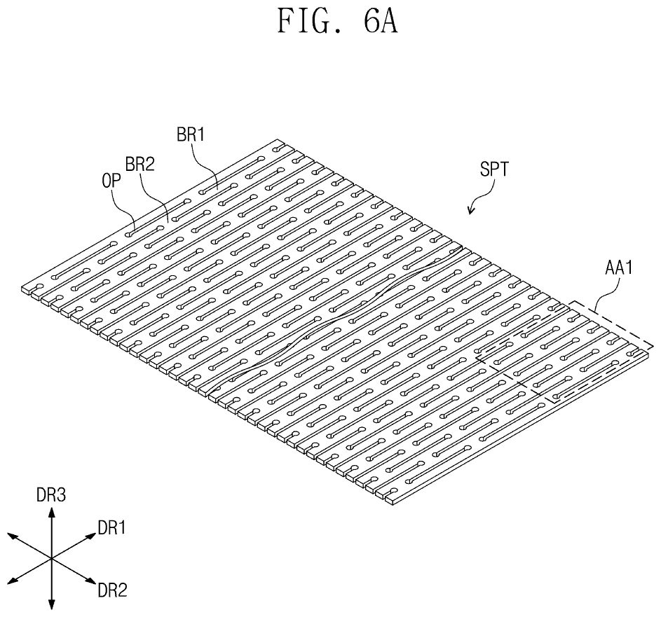

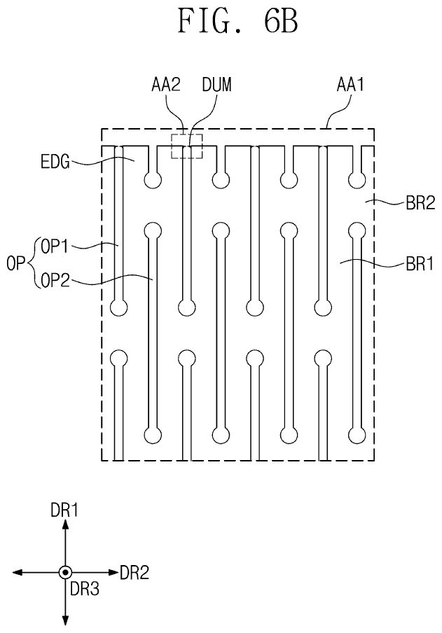

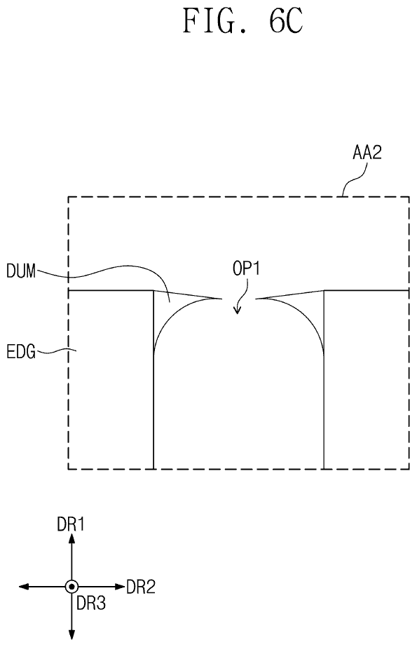

In an embodiment, the support sheet SPT may extend in the second direction DR2 and be wound on the shaft SFT. A first end of the support sheet SPT may be connected to the shaft SFT, and a second end of the support sheet SPT may be connected to the handle HND. The second end of the support sheet SPT may be disposed adjacent to the housing opening HOP. A portion of the support sheet SPT may be wound on the shaft SFT, and another portion of the support sheet SPT may be arranged to overlap the support SUP without being wound on the shaft SFT. The support sheet SPT will be described in detail in FIGS. 6A and 6B.

In an embodiment, the support part MSP may be disposed on one surface of the support sheet SPT. The one surface of the support sheet SPT may be defined as a surface that is disposed opposite to the front surface of the support sheet SPT facing the one surface of the display module DM. The support sheet SPT may be disposed between the display module DM and the support part MSP.

In an embodiment, the support part MSP may extend in the second direction DR2 to be wound on the shaft SFT. A first end of the support part MSP may be connected to the shaft SFT, and a second end of the support part MSP may be connected to the handle HND. At least one of the display module DM, the support sheet SPT, and the support part MSP may be connected to the handle HND. The second end of the support part MSP may be disposed adjacent to the housing opening HOP. A portion of the support part MSP may be wound on the shaft SFT, and another portion of the support part MSP may be arranged to overlap the support SUP without being wound on the shaft SFT.

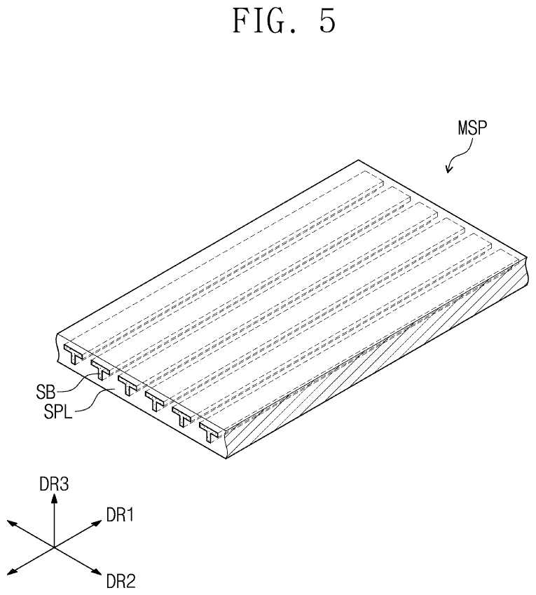

In an embodiment, the support part MSP may include a support layer SPL disposed under the support sheet SPT and a plurality of support bars SB disposed within the support layer SPL. When viewed in the first direction DR1, the support bars SB overlapping the support SUP may be arranged in the second direction DR2. The support layer SPL and the support bars SB will be described in detail in FIG. 5.

In an embodiment and referring to FIG. 2B, the handle HND may be moved in a direction opposite to the second direction DR2 to be away from the housing HS. According to the movement of the handle HND, the display module DM, the support sheet SPT, and the support part MSP connected to the handle HND may be moved in the direction opposite to the second direction DR2.

In an embodiment, the display module DM, the support sheet SPT, and the support part MSP may be unwound from the shaft SFT, and the display module DM, the support sheet SPT, and the support part MSP which are unwound may be pulled out of the housing HS through the housing opening HOP. When the display module DM is in the open mode exposed to the outside of the housing HS, the exposed portion of the display module DM may be extended.

In an embodiment, when the display module DM, the support sheet SPT, and the support part MSP are pulled out from the housing HS according to the movement of the handle HND, the support SUP connected to the handle HND may extend out of the housing HS through the housing opening HOP. The support SUP may extend outside the housing HS and support the display module DM outside the housing HS. For example, the support part MSP and the support sheet SPT moved outside the housing HS may be supported by the support SUP, and the support part MSP and the support sheet SPT supported by the support SUP may support the display module DM.

In an embodiment, the support SUP may include a first extension part EX1, a second extension part EX2, and a third extension part EX3 to extend outside the housing HS, where the second extension part EX2 may be disposed between the first extension part EX1 and the third extension part EX3.

In order to have a structure that is extendable like an antenna, the second extension part EX2 may be inserted into and pulled out from the first extension part EX1, and the third extension part EX3 may be inserted into and pulled out from the second extension part EX2. The first extension part EX1 is at least partially disposed within the housing HS, and the second extension part EX2 and the third extension part EX3 may be moved out of the housing HS. The third extension part EX3 may be connected to the handle HND.

In an embodiment, guide grooves GG may be defined in the first extension part EX1, the second extension part EX2, and the third extension part EX3, respectively. The guide grooves GG defined in the first extension part EX1, the second extension part EX2, and the third extension part EX3 may be defined as continuous spaces that overlap each other in the second direction DR2. The support part MSP may be disposed in the guide grooves GG.

In an embodiment, when the handle HND moves in the second direction DR2 to be closer to the housing HS, the handle HND may be disposed on the outside of the housing HS to be disposed adjacent to the housing opening HOP as illustrated in FIG. 2A. According to the movement of the handle HND, the support SUP may be shortened in the second direction DR2 to be disposed within the housing HS, and the display module DM, the support sheet SPT, and the support part MSP may be inserted into the housing HS to be in a closed state.

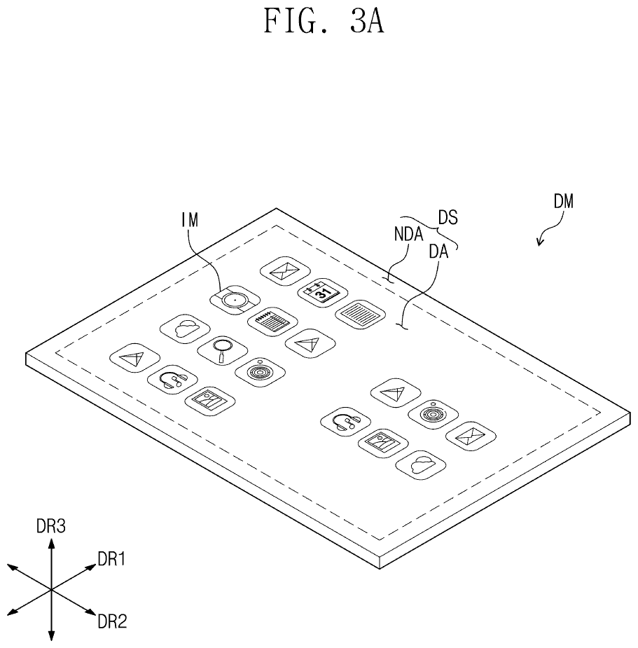

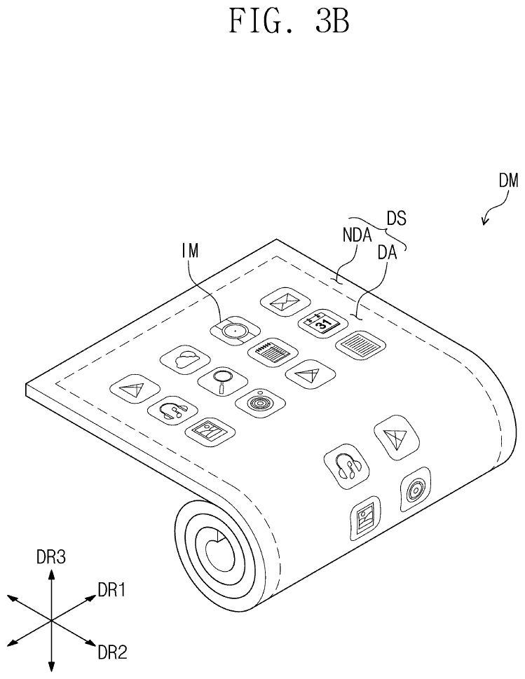

FIGS. 3A and 3B are views illustrating a display module accommodated in a housing illustrated in FIG. 2A, according to an embodiment.

In an embodiment and referring to FIG. 3A, the front surface of the display module DM may be defined as a display surface DS and may have a plane defined by the first direction DR1 and the second direction DR2. Images IM created in the display module DM may be provided to a user through the display surface DS.

In an embodiment, the display surface DS may include a display area DA and a non-display area NDA disposed around the display area DA. The display area DA may display an image, and the non-display area NDA may not display an image. The non-display area NDA may surround the display area DA and may define the edge of the display module DM, which is printed in a predetermined color.

In an embodiment, the display module DM may be a flexible display module. As illustrated in FIG. 3B, the display module DM may be rolled up like a scroll. The display module DM may be rolled in the second direction DR2. The display module DM may be rolled up starting from the first side of the display module DM. The display module DM may be rolled up such that the display surface DS faces outward.

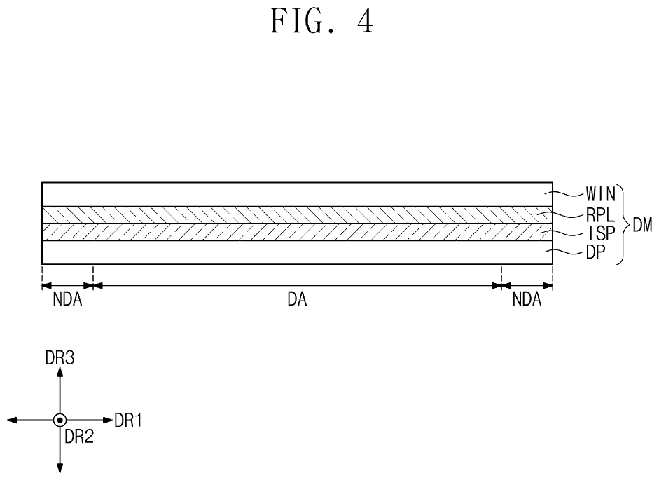

FIG. 4 is a view illustrating the cross section of the display module illustrated in FIGS. 3A, according to an embodiment.

In an embodiment and referring to FIG. 4, the display module DM may include a display panel DP, an input sensing part ISP, a reflection prevention layer RPL, and a window WIN.

In an embodiment, the display panel DP may be a flexible display panel. The display panel DP may be a light-emitting display panel and is not particularly limited thereto. For example, the display panel DP may be an organic light-emitting display panel or an inorganic light-emitting display panel. The light-emitting layer of the organic light-emitting display panel may include an organic light-emitting material. The light-emitting layer of the inorganic light-emitting display panel may include quantum dots and quantum rods. Hereinafter, the display panel DP is described as the organic light-emitting display panel.

In an embodiment, the input sensing part ISP may be disposed on the display panel DP and may include a plurality of sensor parts (not shown) to detect external inputs in a capacitive manner. The input sensing part ISP may be manufactured directly on the display panel DP when manufacturing the display module DM. However, the input sensing part ISP is not limited thereto, and, in another embodiment, may be manufactured as a panel separate from the display panel DP to be attached to the display panel DP by an adhesive layer.

In an embodiment, the reflection prevention layer RPL may be disposed on the input sensing part ISP and may be formed directly on the input sensing part ISP or may be coupled to the input sensing part ISP by an adhesive layer. The reflection prevention layer RPL may be defined as an external light reflection prevention film. The reflection prevention layer RPL may reduce the reflectance of external light incident from a position above the display device DD (see FIG. 1A) toward the display panel DP.

In an embodiment, when external light directed toward the display panel DP is reflected from the display panel DP and provided back to a user outside, the user may see the external light, as in a mirror. To prevent this phenomenon, the reflection prevention layer RPL may include a plurality of color filters that display the same color as the pixels of the display panel DP.

In an embodiment, the color filters may filter external light to be the same color as the pixels. In this case, the external light may not be visible to a user. However, the reflection prevention layer RPL is not limited thereto, and in another embodiment, may include a polarizing film to reduce the reflectance of external light. The polarizing film may include a phase retarder and/or a polarizer.

In an embodiment, the window WIN may be disposed on the reflection prevention layer RPL and may be formed directly on the reflection prevention layer RPL or may be coupled to the reflection prevention layer RPL by an adhesive layer. The window WIN may protect the display panel DP, the input sensing part ISP, and the reflection prevention layer RPL from external scratches and impacts.

FIG. 5 is a perspective view illustrating a portion of a support part illustrated in FIG. 2A, according to an embodiment.

In an embodiment, the support bars SB may extend in the first direction DR1 and may be arranged in the second direction DR2. For example, in FIG. 5, the support bars SB disposed within the support layer SPL are illustrated with dotted lines. The support bars SB may be spaced at equal intervals apart from each other in the second direction DR2, but the intervals between the support bars SB are not limited thereto.

In an embodiment, the opposite ends of each of the support bars SB may be disposed opposite to each other in the first direction DR1 and may not be disposed within the support layer SPL, but may be exposed to the outside of the support layer SPL. Depending on the manufacturing method of the support part MSP, the opposite ends of the support bar SB may be exposed to the outside.

In an embodiment, when viewed in the first direction DR1, the support bar SB may have a ‘T’ shape, but the shape of the support bar SB is not limited thereto.

In an embodiment, the support bar SB may be of a rigid type. For example, the support bar SB may include a reinforced fiber composite, where the reinforced fiber composite may be carbon fiber reinforced plastic (CFRP) or glass fiber reinforced plastic (GFRP). However, the support bars SB is not limited thereto, but may include metal.

In an embodiment, the support layer SPL may include an elastomer having a predetermined elastic force. For example, the support layer SPL may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, and ethylene-vinyl acetate. The support bars SB may have a greater modulus than the support layer SPL.

FIG. 6A is a perspective view of the support sheet illustrated in FIG. 2A, according to an embodiment. FIG. 6B is a plan view of a portion corresponding to a first area AA1 illustrated in FIG. 6A, according to an embodiment. FIG. 6C is a plan view of a portion corresponding to a second area AA2 illustrated in FIG. 6B, according to an embodiment.

For example, the support sheet SPT shown in FIG. 6A is in a flat unfolded state.

In an embodiment, the description of the same components as components described with reference to the above-described drawings among components illustrated in FIGS. 6A to 6C will be omitted or simplified.

In an embodiment and referring to FIGS. 6A and 6B, the support sheet SPT may include aluminum, stainless steel, or Invar. Additionally, the support sheet SPT may include metal that attaches to a magnet. However, the material of the support sheet SPT is not limited thereto. For example, in an embodiment, the support sheet SPT may include a reinforced fiber composite.

In an embodiment, a plurality of openings OP may be defined in the support sheet SPT, where the openings OP may be formed through portions of the support sheet SPT in the third direction DR3. The openings OP may be formed through a laser process or a micro-blasting process.

In an embodiment, the openings OP may be arranged in a predetermined pattern. The openings OP may be arranged in a grid form, forming a grid pattern on the support sheet SPT. Since the openings OP are defined in the support sheet SPT, the area of the support sheet SPT may be reduced, thereby lowering the rigidity of the support sheet SPT. Accordingly, when the openings OP are defined in the support sheet SPT, the flexibility of the support sheet SPT may be increased more than when the openings OP are not defined in the support sheet SPT. As a result, the support sheet SPT may be more easily wound on or unwound from the shaft SFT (see FIG. 2A).

In an embodiment, each of the openings OP may extend in the first direction DR1. The length in the second direction DR2 of each of the opposite ends of the opening OP disposed opposite to each other in the first direction DR1 may be larger than the length of the second direction DR2 of the center of the opening OP. For example, each of the opposite ends of the opening OP disposed opposite to each other in the first direction DR1 may have a shape corresponding to a portion of a circle.

In an embodiment and as illustrated in FIG. 6B, the openings OP may include a plurality of first openings OP1 arranged in the first direction DR1 and a plurality of second openings OP2 arranged in the first direction DR1 by being disposed adjacent to the first openings OP1 in the second direction DR2. The first openings OP1 may be arranged to be staggered with the second openings OP2.

In an embodiment, the support sheet SPT may include first branch parts BR1, second branch parts BR2, and a plurality of dummy parts DUM. Each of the first branch parts BR1 may be disposed between each of the first openings OP1 and each of the second openings OP2 adjacent to each other in the second direction DR2. Each of the second branch parts BR2 may be disposed between the first openings OP1 which are disposed adjacent to each other in the first direction DR1 or between the second openings OP2 which are disposed adjacent to each other in the first direction DR1.

In an embodiment, the length of the first opening OP1 disposed adjacent to the edge of the support sheet SPT may be greater than the length of the second opening OP2 disposed adjacent to the edge of the support sheet SPT.

In an embodiment, the first branch parts BR1 disposed in an area corresponding to the edge of the support sheet SPT may be defined as edge parts EDG. The inner sides of the edge parts EDG may be exposed to the outside of the support sheet SPT. The openings OP defined in the edge of the support sheet SPT may be defined as continuous with the outside of the support sheet SPT. The inner sides of the edge parts EDG may be defined as the inner surfaces of the support sheet SPT, in which the openings OP are defined.

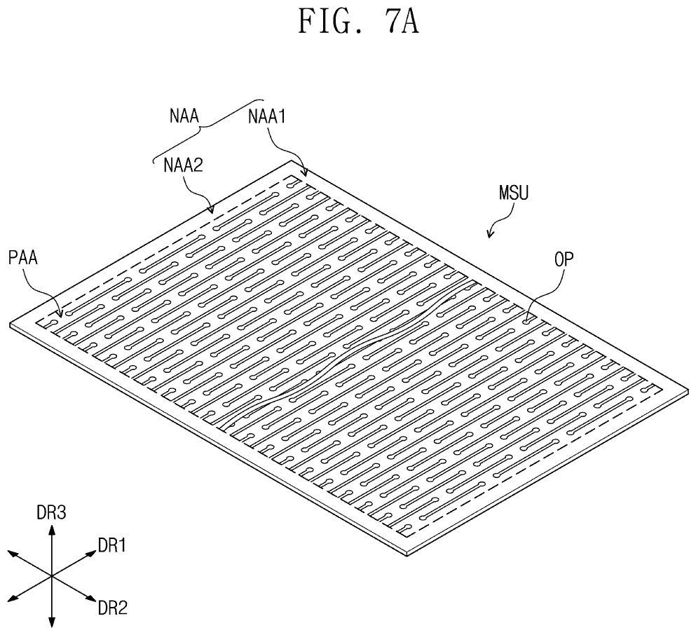

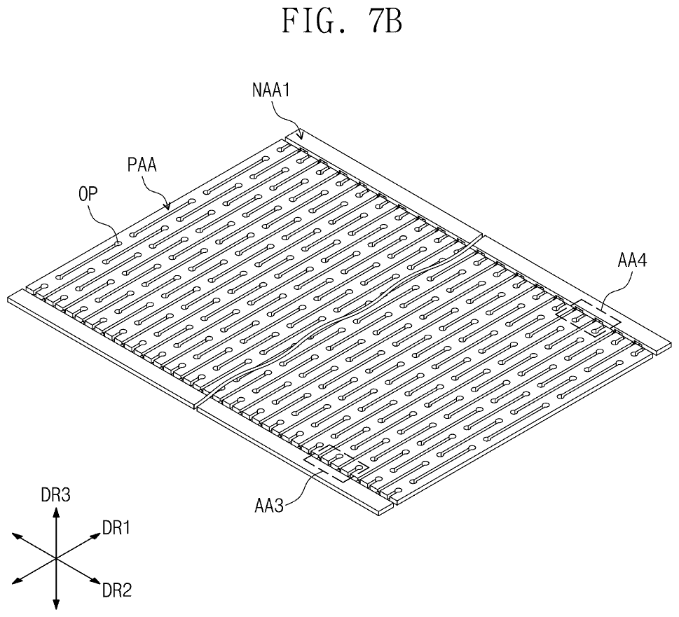

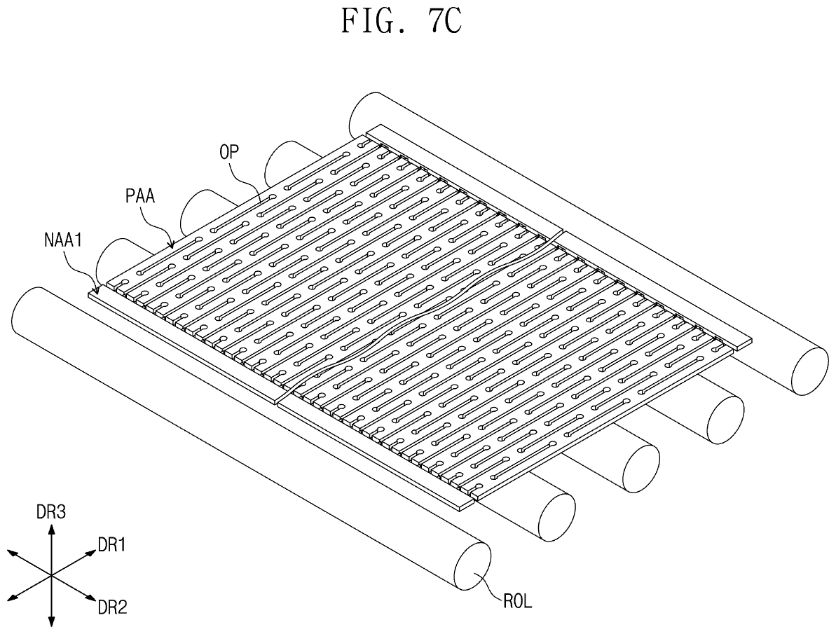

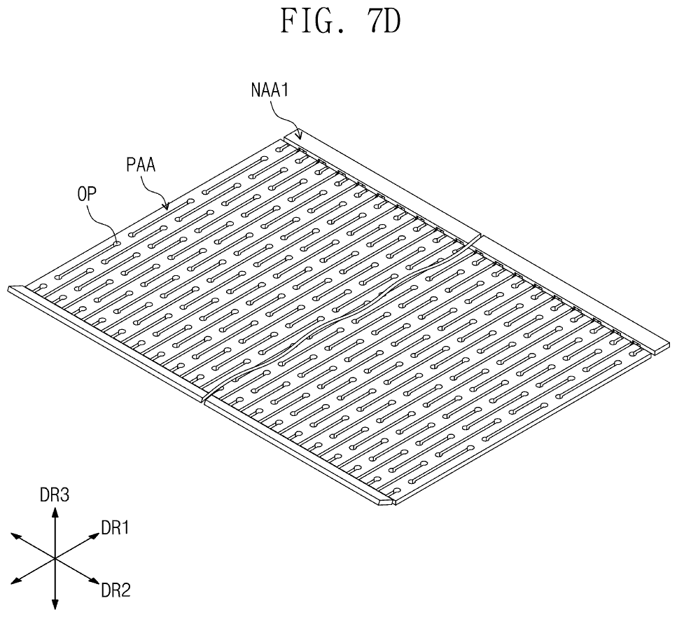

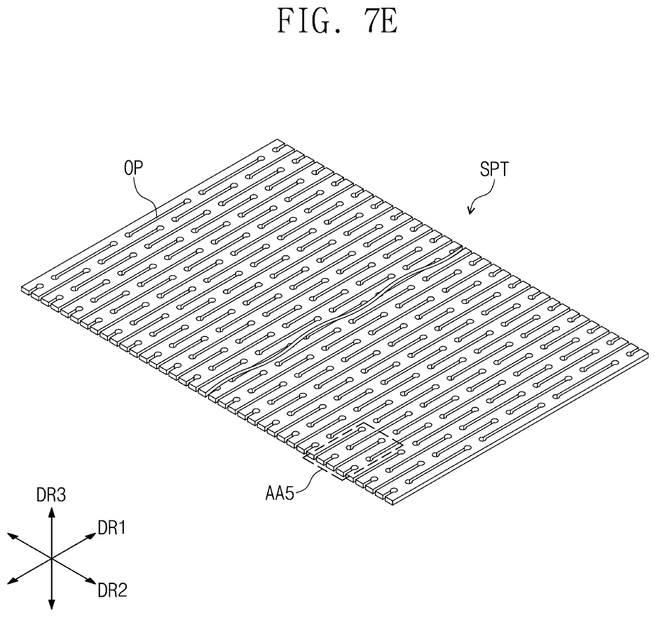

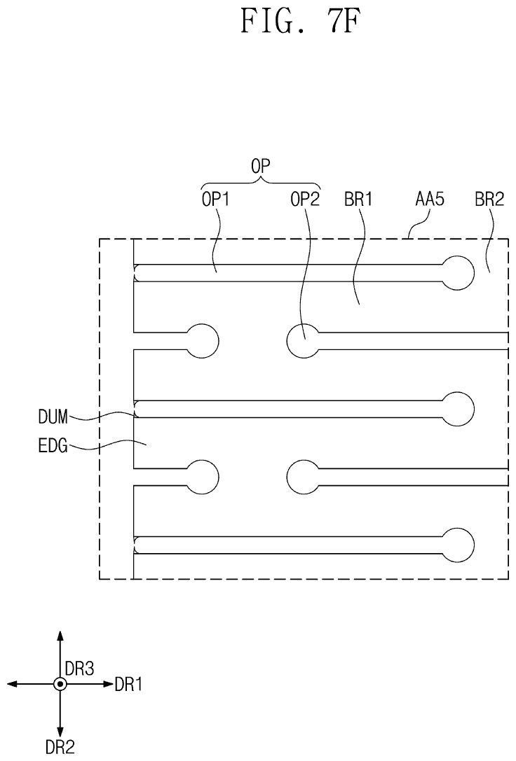

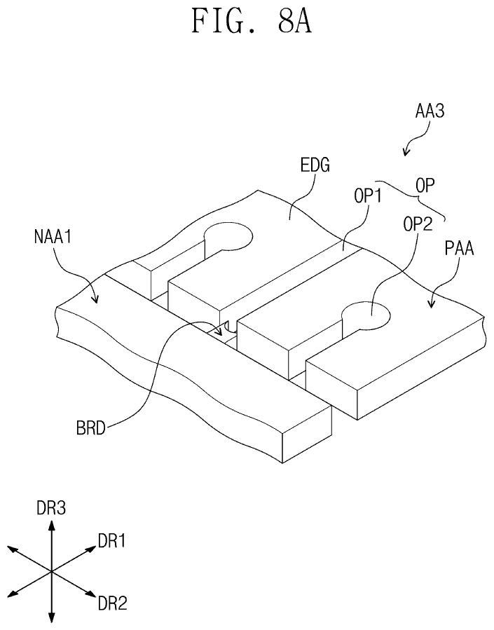

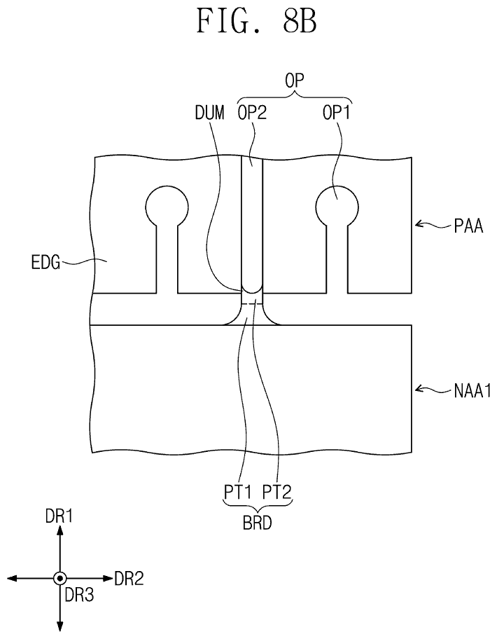

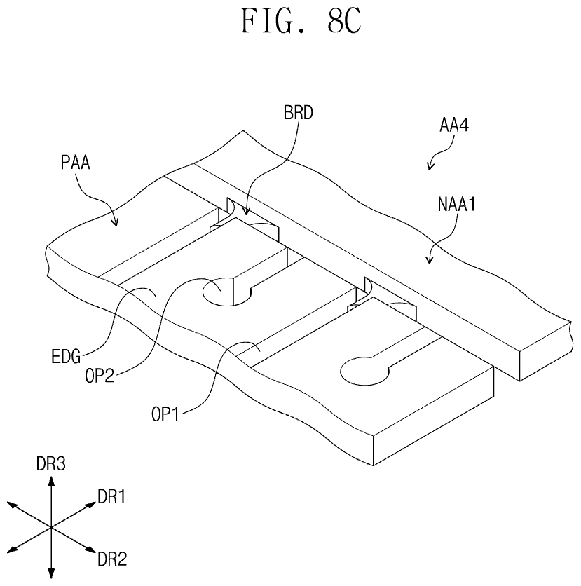

In an embodiment and referring to FIGS. 6B and 6C, the dummy parts DUM may be disposed on the inner sides of the edge parts EDG, where each of the dummy parts DUM may be a residue of each of the bridges BRD (see FIG. 8A) generated when separating a pattern part PAA and a peripheral part NAA of FIG. 7D from each other. The description of the dummy parts DUM will be described in detail in FIG. 7F.

In an embodiment, when viewed on a plane, the dummy parts DUM may be disposed within at least one of the first opening OP1 or the second opening OP2. For example, in FIG. 6B, the dummy parts DUM may be disposed within the first opening OP1. The dummy parts DUM may face each other in the second direction DR2 within the first opening OP1 and may be spaced apart from each other in the second direction DR2.

In an embodiment, when viewed on a plane, the dummy parts DUM may not protrude more outward than each of the edge parts EDG. Since the dummy parts DUM are not exposed to the outside of the edge part EDG, the dummy parts DUM may not be in contact with the display module DM (see FIG. 2A) when the support sheet SPT is attached to the one surface of the display module DM (see FIG. 2A). Accordingly, the possibility of damage to the display module DM (see FIG. 2A) may be reduced, and the defect rate of the display device DD (see FIG. 2A) may be improved.

In an embodiment, when viewed on a plane, the length of each of the dummy parts DUM in the second direction DR2 may be smaller than half the length of the first opening OP1 in the second direction DR2. When viewed on a plane, among the opposite sides of the dummy part DUM disposed opposite to each other in the first direction DR1, one side of the dummy part DUM disposed adjacent to the second branch part BR2 may have a curved surface.

FIGS. 7A to 7F are views for describing a manufacturing method of the support sheet illustrated in FIG. 6A, according to an embodiment. FIG. 8A is a perspective view of a portion corresponding to a third area AA3 illustrated in FIG. 7B, according to an embodiment. FIG. 8B is a plan view of FIG. 8A. FIG. 8C is a perspective view of a portion corresponding to a fourth area AA4 illustrated in FIG. 7B, according to an embodiment.

The description of the same components as components described with reference to the above-described drawings among components illustrated in FIGS. 7A to 8C will be omitted or simplified.

For example, FIGS. 7A to 7E are perspective views, and FIG. 7F is a plan view corresponding to a fifth area AA5 illustrated in FIG. 7E.

In an embodiment and referring to FIG. 7A, the manufacturing method of the support sheet may include preparing a mother substrate MSU including the pattern part PAA and the peripheral part NAA. The mother substrate MSU may have a rectangular shape with short sides extending in the first direction DR1 and long sides extending in the second direction DR2. The pattern part PAA may be referred to as a preliminary pattern part PAA.

In an embodiment, the pattern part PAA may have a rectangular shape defined by the first direction DR1 and the second direction DR2. The peripheral part NAA may surround the pattern part PAA. The peripheral part NAA may include first peripheral parts NAA1 disposed adjacent to the long sides of the pattern part PAA and second peripheral parts NAA2 disposed adjacent to the short sides of the pattern part PAA.

In an embodiment, after the mother substrate MSU is prepared, the openings OP may be formed by etching the mother substrate MSU, where the plurality of openings OP may be defined in the pattern part PAA. For example, the openings OP may be formed through a laser, but are not limited thereto and may be formed through a micro-blasting process. Since the openings OP has been described in detail in FIG. 6B, the description of the openings OP will be omitted.

In an embodiment and referring to FIGS. 7B and 7C, after the openings OP are formed, forming the bridges BRD (see FIG. 8A) may be performed. The second peripheral parts NAA2 in the peripheral part NAA may be separated and removed from the pattern part PAA. The first peripheral parts NAA1 may be respectively connected to the opposite sides of the pattern part PAA disposed opposite to each other in the first direction DR1.

In an embodiment and as illustrated in FIG. 7C and FIG. 7D, the pattern part PAA and the first peripheral parts NAA1 may be transported through rollers ROL. In this case, since the first peripheral parts NAA1 are respectively disposed on the opposite sides of the pattern part PAA, the opposite sides of the pattern part PAA may be prevented from colliding with the rollers ROL. Accordingly, damage to the pattern part PAA may be prevented.

In an embodiment and referring to FIGS. 8A and 8C, the pattern part PAA and each of the first peripheral parts NAA1 may be connected to each other by the plurality of bridges BRD which may be formed by etching the first peripheral part NAA1 disposed adjacent to a border between the pattern part PAA and the first peripheral part NAA1. The bridges BRD may be formed by etching a portion that is equivalent to half the thickness of the first peripheral part NAA1.

In an embodiment, the thickness of each of the bridges BRD may be smaller than the thickness of the first peripheral part NAA1 and smaller than the thickness of the pattern part PAA. The height of the upper surface of the bridge BRD may be lower than the height of the upper surface of the pattern part PAA and lower than the height of the upper surface of the first peripheral part NAA1. As the thickness of the bridge BRD decreases, the rigidity of the bridge BRD may also decrease. Accordingly, as illustrated in FIG. 7D, when separating the first peripheral part NAA1 and the pattern part PAA from each other, the bridges BRD may be easily cut. Accordingly, the manufacturing of the support sheet SPT (see FIG. 6A) may be easy.

In an embodiment and referring to FIGS. 7D and 8B, each of the bridges BRD may include a first part PT1 and a second part PT2, where a portion of the bridge BRD that is disposed adjacent to the first peripheral part NAA1 may be defined as the first part PT1. A portion of the bridge BRD disposed adjacent to the pattern part PAA may be defined as the second part PT2.

In an embodiment, the first part PT1 may be disposed on one side of the first peripheral part NAA1 facing the pattern part PAA. When viewed on a plane, the width of the first part PT1 in the second direction DR2 may be varied. The width of the first part PT1 in the second direction DR2 may gradually decrease as the first part PT1 extends from the first peripheral part NAA1.

In an embodiment, when viewed in a plane, the opposite sides of the first part PT1 disposed opposite to each other in the second direction DR2 may include curved shapes. The opposite sides of the first part PT1 disposed opposite to each other in the second direction DR2 may include concave surfaces.

In an embodiment, the second part PT2 may extend from the first part PT1 in the first direction DR1 and may be disposed between the edge parts EDG that are located adjacent to each other in the second direction DR2. The second part PT2 may be disposed on the inner sides of the edge parts EDG defining the first openings OP1. Portions of the second part PT2 disposed on the inner sides of the edge parts EDG may be defined as the dummy parts DUM, where the dummy parts DUM may be spaced further apart from the first peripheral part NAA1 than the sides of the edge parts EDG.

In an embodiment, when viewed on a plane, each of the opposite sides of the second part PT2 disposed opposite to each other in the second direction DR2 may have a rectilinear shape extending in the first direction DR1. When viewed on a plane, an angle between each of the opposite sides of the second part PT2 disposed opposite to each other in the second direction DR2 and one side of the pattern part PAA facing the first peripheral part NAA1 may be in a range of about 85 degrees to about 95 degrees. When viewed on a plane, an angle between each of the opposite sides of the second part PT2 disposed opposite to each other in the second direction DR2 and the one side of the pattern part PAA facing the first peripheral part NAA1 may preferably be a right angle. Here, a right angle may include not only a mathematical right angle but also a substantially right angle.

In an embodiment, when viewed on a plane, a first side of the opposite sides of the second part PT2 disposed opposite to each other in the first direction DR1 may have a curved shape. The first side of the opposite sides of the second part PT2 disposed opposite to each other in the first direction DR1 may be defined as a side spaced apart from the first part PT1. The first side of the second part PT2 may have a concave surface.

In an embodiment, since the first side of the second part PT2 has the concave surface, the area of the second part PT2 disposed adjacent to the one side of the pattern part PAA may decrease. When viewed on a plane, the area of the second side of the second part PT2 disposed adjacent to the first part PT1 may be larger than the area of the first side of the second part PT2. The area of the dummy part DUM may decrease as a distance between the dummy part DUM and the first part PT1 increases.

In an embodiment and referring to FIGS. 7D to 7F, and 8B, when separating the first peripheral part NAA1 and the pattern part PAA from each other, stress may occur in the bridge BRD. Since the opposite sides of the first part PT1 have curved shapes and the opposite sides of the second part PT2 have rectilinear shapes, stress may be concentrated on the second part PT2. Stress may be concentrated on a portion located adjacent to the first side of the second part PT2 with a relatively small area of the opposite sides of the second part PT2 disposed opposite to each other in the first direction DR1. Stress may be concentrated on the dummy parts DUM disposed within the opening OP. Accordingly, as illustrated in FIG. 7F, the second part PT2 (see FIG. 8B) may be cut, the dummy parts DUM may be cut and the pattern part PAA separated from the first peripheral parts NAA1 may be defined as the support sheet SPT of FIG. 7E.

In an embodiment and as illustrated in FIG. 7F, the cut dummy parts DUM may remain in the opening OP, where the dummy parts DUM may not protrude outward from the opening OP and where the dummy parts DUM may be disposed on the inner sides of the edge parts EDG. When viewed on a plane, the dummy parts DUM may not protrude more outward than the sides of the support sheet SPT. The dummy parts DUM may not protrude more outward than the sides of the edge parts EDG.

Accordingly, in an embodiment and as illustrated in FIGS. 2A and 2B, when the support sheet SPT is coupled to the display module DM, the dummy parts DUM may not be in contact with the display module DM, and thus the display module DM may not be damaged. Accordingly, the defect rate of the display device may be reduced.

Additionally, as illustrated in FIGS. 2A and 2B, the support sheet SPT may be coupled to the one surface of the display module DM.

According to an embodiment of the invention, the pattern part and the peripheral part may be connected to each other through the bridge, where the bridge may have a smaller thickness than the pattern part and the peripheral part. Accordingly, the pattern part and the peripheral part may be easily separated from each other, thereby facilitating the manufacturing of the support sheet.

According to an embodiment of the invention, the dummy part DUM, which is defined as a residue generated during manufacturing, is disposed within the opening, and may not protrude more outward than the side of the support sheet SPT. Accordingly, it is possible to reduce the defect rate of the display device.

While the invention has been described with reference to embodiments thereof, it will be apparent to those of ordinary skill in the art that various changes and modifications may be made thereto without departing from the spirit and scope of the invention. In addition, embodiments disclosed herein are not intended to limit the technical spirit of the invention, and all technical spirits within the scope of the invention and a scope equivalent thereto should be interpreted as being included in the scope of the invention. Accordingly, embodiments disclosed herein are not intended to limit the technical spirit of the invention, and all technical ideas disclosed herein should be construed as being included in the scope of the invention. Moreover, embodiments or parts of the embodiments may be combined in whole or in part without departing from the scope of the invention.

What is claimed is:

1. A manufacturing method of a display device, the method comprising:
preparing a mother substrate including a pattern part and a peripheral part, wherein the peripheral part is disposed on an outside of the pattern part;
forming an opening by etching the pattern part;
forming a bridge by etching a portion of the peripheral part adjacent to a border between the pattern part and the peripheral part;
separating the pattern part and the peripheral part from each other by cutting the bridge; and
coupling the pattern part on one surface of a display module,
wherein a thickness of the bridge is smaller than a thickness of the pattern part.

2. The method of claim 1, wherein the bridge includes:
a first part disposed adjacent to the peripheral part; and
a second part extending in a first direction from the first part and to be disposed adjacent to the pattern part.

3. The method of claim 2, wherein when viewed on a plane, each of an opposite side of the first part disposed opposite to each other in a second direction intersecting the first direction has a curved shape.

4. The method of claim 3, wherein when viewed on the plane, each of an opposite side of the second part disposed opposite to each other in the second direction has a rectilinear shape, and
when viewed on the plane, each of the opposite sides of the second part disposed opposite to each other in the second direction and one side of the pattern part form an angle in a range of about 85 degrees to about 95 degrees, wherein the one side of the pattern part is defined as a side facing the peripheral part.

5. The method of claim 4, wherein a first side of the opposite sides of the second part disposed opposite to each other in the first direction has a curved shape disposed within the opening.

6. The method of claim 4, wherein a first side of the opposite sides of the second part disposed opposite to each other in the first direction is disposed within the opening, and
wherein an area of a second side of the second part disposed adjacent to the first part is larger than an area of a first side of the second part.

7. The method of claim 1, wherein a height of an upper surface of the bridge is lower than a height of an upper surface of the pattern part.

8. The method of claim 7, further comprising:
transporting, through a roller, the mother substrate in which the bridge is formed before cutting the bridge, but after forming the bridge,
wherein in the transporting, a lower surface of the bridge is in contact with the roller.

9. The method of claim 1, wherein the bridge extends in a first direction toward the pattern part from the peripheral part and has a width decreasing gradually in a second direction intersecting the first direction toward the pattern part from the peripheral part.

10. The method of claim 9, wherein the bridge includes:
a first part disposed adjacent to the peripheral part; and
a second part extending in the first direction from the first part and to be disposed adjacent to the pattern part,
wherein a maximum width of the first part in the second direction is larger than a maximum width of the second part in the second direction.

11. The method of claim 10, wherein each of an opposite side of the first part disposed opposite to each other in the second direction has a curved surface.

12. The method of claim 10, wherein a portion of the second part disposed within the opening is defined as a dummy part, and
when viewed on a plane, an area of the dummy part decreases as a distance between the dummy part and the first part increases.

13. A display device comprising:
a display module;
a support part disposed under the display module; and
a support sheet disposed between the display module and the support part,
wherein the support sheet includes:
a plurality of openings arranged in a first direction and a second direction intersecting the first direction;
a first branch part disposed between the plurality of openings arranged in the second direction;
a second branch part disposed between the plurality of openings arranged in the first direction; and
a dummy part disposed in an opening, among the plurality of openings, disposed adjacent to an edge of the support sheet,
wherein the dummy part has a shape protruding from the second branch part in the second direction.

14. The display device of claim 13, wherein when viewed on a plane, the dummy part does not protrude outward from the opening.

15. The display device of claim 13, wherein a thickness of the dummy part is smaller than a thickness of the first branch part and is smaller than a thickness of the second branch part.

16. The display device of claim 13, wherein the opening disposed adjacent to the edge of the support sheet includes a first opening, and a second opening disposed adjacent to the first opening in the second direction,
wherein a length of the first opening is longer than a length of the second opening, and
wherein the dummy part is disposed within the first opening.

17. The display device of claim 16, wherein a length of the dummy part in the second direction is smaller than half of a length of the first opening in the second direction.

18. The display device of claim 16, wherein the dummy part includes a plurality of dummy parts,
wherein the plurality of dummy parts are arranged within the first opening to be spaced apart from each other in the second direction.

19. The display device of claim 15, wherein among opposite sides of the dummy part disposed opposite to each other in the first direction, one side of the dummy part disposed adjacent to the second branch part has a curved surface.

20. An electronic device, comprising:
a display device, wherein the display device comprises,
a display module;
a support part disposed under the display module; and
a support sheet disposed between the display module and the support part,
wherein the support sheet includes:
a plurality of openings arranged in a first direction and a second direction intersecting the first direction;
a first branch part disposed between the plurality of openings arranged in the second direction;
a second branch part disposed between the plurality of openings arranged in the first direction; and
a dummy part disposed in an opening, among the plurality of openings, disposed adjacent to an edge of the support sheet,
wherein the dummy part has a shape protruding from the second branch part in the second direction.
